(19) United States
(12) Patent Application Publication
(10) Pub. No.: US 2014/0318605 A1
(43) Pub. Date: Oct. 30, 2014

(54) PANEL RACK SUPPORT AND PROTECTIVE SYSTEM FOR STACKING

(71) Applicants: Gregory P. Huzyak, Salem, OH (US); Michael G. Greenamyer, Youngstown, OH (US)

(72) Inventors: Gregory P. Huzyak, Salem, OH (US); Michael G. Greenamyer, Youngstown, OH (US)

(73) Assignee: Northern States Metals Company, West Hartford, CT (US)

(21) Appl. No.: 14/263,161

(22) Filed: Apr. 28, 2014

Related U.S. Application Data
(60) Provisional application No. 61/817,412, filed on Apr. 30, 2013.

(51) Int. Cl. H01L 31/042

(52) U.S. Cl. CPC H01L 31/0422
USPC 136/251

(57) ABSTRACT

A solar panel protection and alignment system is constituted by the deployment of at least one crib structure between four adjacent solar panels. The crib structure includes two interlocking perpendicular pieces providing support and panel alignment.

### PRIORITY INFORMATION

The present application claims priority to U.S. Provisional Patent Application No. 61/817,412 filed Apr. 30, 2013, incorporated herein in its entirety.

### FIELD OF INVENTION

The present invention relates generally to the field of panel support and protection. In particular, the present invention is directed to a system for aligning and protecting solar panels during transit from a first location for subsequent assembly and/or installation of the overall solar panel array at a second location.

### BACKGROUND ART

The solar panel market, including the structures supporting the panels, constitute a dynamic environment, constantly evolving as the technology changes and improves. However, there are prosaic factors dictated by the market conditions, rather than technology. These include the expense and ease of installation, and the allocation of capital investment to installation contractors.

It should be understood that installation costs for solar panel arrays constitute a major capital expenditure that must be factored into the overall cost/benefit analysis of using solar panel arrays. A major factor in this cost benefit analysis is the chance of destruction or degradation of the solar panels during transport and installation. Consequently, a major part of this activity includes protecting the fragile solar panels themselves. Those who provide the support structure arrays for solar panels must constantly increase the ease, and decrease the expenditure of installation.

Currently, the solar panel market has evolved to the point that installation costs from a contracting installer constitutes a major capital expenditure that has substantially added to the cost of the overall solar panel system. Installation costs from contractors typically constitute a fixed expenditure in the purchase of solar panel arrays. Unfortunately, improvements in the base of installation of solar panel support structures do very little to change this apparent fixed cost.

Conventionally, solar panel arrays have been erected at the installation site very much like a conventional erector set, with each of the pieces being shipped to the site, and then being assembled from the ground up. Typically, substrate supports are pre-installed, and the array assembled to the substrate supports on a piece-by-pieces basis. This has always constituted a major difficulty since assembly of the solar panel array was often inaccurate, always very time-consuming, and occasionally constituted a hazard to both personnel and the delicate solar panels themselves.

One approach to these difficulties was undertaken through implementation of folding panel arrays, so that the entire panel support system could be folded into one structure and shipped. Then, the structure was lifted from the truck, unfolded and placed on the substrate supports. Afterwards, the solar panels were individually connected to the unfolded or deployed support array. While this arrangement saved a great deal of time and installation expense, it made little impact in the market where installation costs were always fixed regardless of the type of support system being used.

Consequently, there has been a trend in the solar panel market to ship solar panels already attached to segments of panel support systems. This means that the solar panels are shipped on segments of assembled support systems in a generally exposed condition. An example of such arrangement is found with Unirac® projects which utilize support rack segments which include a column of three or four solar panels. Unirac® is a registered trademark owned by Unirac Inc, a New Mexico corporation located at 1411 Broadway Boulevard, N.E., Albuquerque, New Mex.

One example of an installation process for this particular panel and rack arrangement is the use of a sling with four lines connected at a single point to a crane hoist line. Hooks or holders are connected beneath the frames of solar panels on the array at four different points on the solar panel column. The problem with this arrangement is that stress is placed on the edges of the solar panels when the panel support section is lifted into position on a pre-installed substrate support. Even framed solar panels can be severely damaged if the stresses of lifting an entire panel-populated support rack segment are focused on any part of any of the solar panels. Unfortunately, this is often the case. At the very least, panels become misaligned, if not entirely degraded. Any of these conditions will result in a lowered effective life of the overall solar panel array.

The dangers to pre-populated solar panel support rack sections are greatly increased when these sections are stacked on each other for truck transport. While careful handling at the assembly site and the installation site may limit the exposure to damage, road transport on open flat bed trucks, includes sources of damage that cannot be easily controlled. However, there is no other way of moving pre-populated panel support rack sections from an assembly site to an installation site. Further, to make appropriate use of a large, expensive flat bed truck, the panel sections must be stacked on each other as high as the overall weight and strength of the rack sections will accommodate.

Accordingly, there is a need for a system that will operate to protect pre-populated solar panel rack sections for loading, road transport, and installation at designated sites. Such a system would avoid stress to the solar panels while permitting accurate positioning of the pre-populated solar panel support rack sections. Further, the pre-populated solar panel support rack sections would be stackable without damage to the solar panels, regardless of the position of a particular solar panel in the stack of rack sections. The desired support and protective system would serve to maintain panel spacing while protecting a wide range of different panel configurations.

### SUMMARY OF THE INVENTION

It is a primary object of the present invention to provide an alignment system for protecting a panel support system populated with solar panels in a manner that overcomes the drawbacks of the conventional art.

It is an additional object of the present invention to provide a protective system for sections of a module-populated solar panel support rack capable of protecting the solar panels in a wide range of environments and handling conditions.

It is another object of the present invention to provide a solar panel protective system capable of being applied to a wide range of solar panel array sizes and configurations.

It is a further object of the present invention to provide a solar panel protective system that maintains appropriate panel spacing wherever it is needed in the solar panel array system.

It is another object of the present invention to provide a protective system for a module populated solar panel support system, having the capability to adapt to a wide range of panel sizes and spacings.

It is still an additional object of the present invention to provide a solar panel protection system that permits safe, easy stacking of solar panel populated support rack sections.

It is yet a further object of the present invention to provide a solar panel protection system that protects stacked solar panel populated support rack sections for transport on an open, flat bed truck.

It is again an additional object of the present invention to provide a solar panel protection system that facilitates maintenance of panel spacing at all times, including deployment of solar panel populated support rack sections at various angles.

It is yet another object of the present invention to provide a solar panel protection and alignment system that can be easily added to various parts of a solar panel array.

It is yet a further object of the present invention to provide a solar panel protection system that can be easily removed once the solar panels are fully deployed and secured.

It is yet an additional object of the present invention to provide a solar panel protection system that is highly economical so that its various parts can be reused or easily discarded.

These and other goals and objects of the present invention are achieved by a panel array having multiple adjacent panels with at least one space therebetween. The panel array is supported by a multi-tiered, two-directional support system having at least a plurality of panel rails supported by multiple structural elements of a lower support tier. Also included is a panel separation and protection system arranged between at least two of the panels. That panel separation system includes at least one support piece arranged in a first space between at least two adjacent panels, and an alignment piece, interlocking with the support piece and arranged substantially perpendicular to the support piece. The alignment piece is arranged to hold the support piece in place.

In another embodiment of the present invention, a method of protecting sections of panels, which are grouped on segments of two-dimensional, multi-tier support arrays, is used for stacking the panel-populated segments. The support arrays have at least upper panel rails and lower support tiers. In the method, the panels are attached to upper panel rails with at least multiple segments. Then, protectors are placed in selected spaces between adjacent panels so that they extend above those panels. The protectors rest on at least part of the two-dimensional, multi-tier support array of the segment. Alignment pieces are attached to lock with the protectors to maintain the protectors in position. Once this has been done, multiple segments can be stacked on each other so that the lower support tier elements of an upper segment are resting on at least one of the protectors of a lower segment.

### BRIEF DESCRIPTION OF THE DRAWINGS

While the following drawings are sufficient to describe all aspects of the present invention by themselves, Appendix 1 is attached hereto, including photographs of various aspects of the present invention, as a supplement to the subject drawings.

FIG. 1 is a front view of the crib structure, deployed on the solar panel rack section.

FIG. 2 is a perspective view of the support piece interlocked with a front view of the alignment piece.

FIG. 3 is a side view of the support piece.

FIG. 4 is a side view of the alignment piece.

FIG. 5A is a side view of stacked solar panel support sections employing the present inventive system on a flat bed trailer.

FIG. 5B is a detailed view of a portion of FIG. 5A, depicting the use of the present invention as deployed to accommodate a stack of solar panel support sections.

FIG. 6 is a side view of a second embodiment of the crib structure of the present invention.

FIG. 7 is a side view of the alignment piece of the crib structure of FIG. 6.

FIG. 8 is a side view of the support structure of FIG. 6.

FIG. 9 is a side view of the crib structure of the second embodiment of the present invention as deployed with a solar panel support system having only a single support element.

FIG. 10 is a perspective view of the second embodiment of the present invention.

FIG. 11A is a side view of a trailer loaded with support rack sections on which the second embodiment of the present invention is deployed.

FIG. 11B is a detailed view of one support rack section of FIG. 11A.

FIG. 12A is a top perspective view of the first embodiment of the present invention, as deployed in a panel support array.

FIG. 12B is a bottom perspective view of the first embodiment of the present invention, as deployed in a panel support array.

FIG. 13A is an upper perspective view of the second embodiment of the present invention, as deployed in a panel support array.

FIG. 13B is a lower perspective view of the second embodiment of the present invention, as deployed in a panel support array.

### DETAILED DESCRIPTION OF THE PREFERRED EMBODIMENTS

The solar panel protection and alignment system of the present invention relies upon selective deployment of crib structures 1 on a solar panel-populated section of a panel support array. Generally, a solar panel support array is constituted by an upper panel rail 30 (vertical Z-rail) and an underlying lower support joist 20 (horizontal Z-purlin). The upper panel rail 30 directly supports solar panel modules 12. These modules can be framed or unframed, and can be attached to the panel rail 30 using a wide variety of techniques. These include panel clips, screws through the frame (not shown) of solar panel module 12, and adhesive holding the active portion of the solar panel directly to panel rail 30.

It should be understood that the upper panel rail 30, while depicted as a Z-purlin, can be virtually any structure that will be appropriate to support a solar panel module 12. Likewise, the lower support joist 20 can be a Z-purlin, or can be constituted by any appropriate structure that would be effective for this particular function.

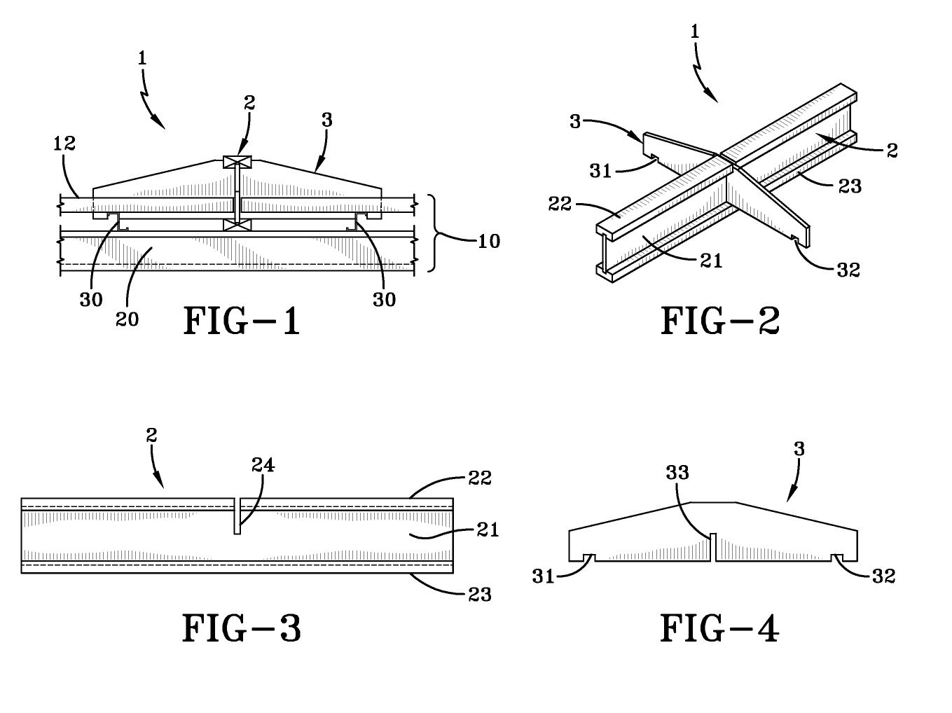

It should also be understood while a two-tier panel support section (panel rail 30 and lower support joist 20) is used, other configurations are also applicable for the present invention. For example, the support array can be constituted by structures that will form panel rails to be installed directly on multiple tilt brackets (not shown) in a manner that is already known in this particular technology. In either case, the cribbing structure 1 will be configured and deployed as it is currently depicted in FIGS. 1-5B.

Each crib structure 1 is constituted by two interlocking, substantially perpendicular pieces. These are support piece 2 and alignment piece 3. Interlocking between these two pieces is achieved by notch 24 in support piece 2 and notch 33 in alignment piece 3. The thickness of alignment piece 3 and the webbing (i.e., intermediate piece) 21 of support piece 2 are adjusted for the spacing between the actual solar panels 12 to be protected. Generally, these thicknesses are between ¼ and ¾ of an inch. However, they can be modified in accordance with the actual solar support array to be protected. When deployed cribbing structure 1 provides spacing at a corner of four adjacent solar panels 12. Because the support piece 2 is interlocked with alignment piece 3, a rigid, stable structure is provided to maintain separation between for adjacent solar panels 12.

Support piece 2, as depicted in FIGS. 1-5B is in the form of an I-beam. This is constituted by the webbing or intermediate piece 21 and upper and lower bearing pieces, 22, 23, respectively. Both the upper and lower bearing pieces 22 and 23 bear against adjacent tiers of panel support sections 10. As depicted in FIGS. 5A and 5B, the middle panel support section 10 is sandwiched between an upper panel support section 10′ and a lower panel support section 10″. The upper bearing piece 22 is in contact with lower support joist 20 of panel support section 10′. Lower bearing piece 23 is in direct contact with lower support joist 20 of panel support section 10. In turn, lower support joist 20 of panel support section 10 rests directly on the upper bearing piece 22 of panel support section 10″, which is immediately beneath panel support section 10.

In this manner, the weight of the top panel support section 10′ is directed through lower support joist 20 of support section 10′ directly to upper bearing piece 22 in the next lower panel support section 10. The weight is transferred through webbing or intermediate piece 21 to the lower bearing piece 23, which in turn rests on lower support joist 20 of panel support section 10. Because webbing 21 is positioned between adjacent solar panels 12 in all layers of the stacked arrangement of FIGS. 5A, 5B, the weight from an upper tier is transmitted directly through the entire height of the webbing piece into the lower bearing piece 23. The lowest tier of the stack, constituted by panel support section 10″ rests on blocks 52, which in turn rests upon the trailer deck 51 of trailer 5.

The number of cribbing structures 1 that are deployed over the various solar panel support racks sections 10, 10′, 10″, depends upon the overall weight and size of the various support rack sections to be handled. While three crib structures 1 are depicted in each tier of FIG. 5A, more can be used, depending upon the overall size and weight of the solar panel support rack sections 10, 10′, 10″. If necessary, a crib structure 1 can be deployed at every corner arrangement of four adjacent solar panel modules 12.

In general, the width of flat bed trailers is limited to approximately eight feet. For maximum protection, the solar panel support rack sections 10 are best kept within those confines due to the fragility of the solar panel modules 12. This limits the size and configurations of panel-populated support rack sections 10. The present invention addresses these limitations.

An open flat bed trailer 5, such as that depicted in FIG. 5A is preferable for transport of solar panel rack sections, using the present invention. In particular, as each tier of solar panel support rack section (10, 10′, 10″) is loaded, the support piece 2 can be slid into place from the side of the trailer. This is possible because there is no bearing load placed on support piece 2 until the next tier of solar support rack section is loaded above the first tier. Once each of the support pieces 2 is installed for a particular tier of solar panel support rack section, the alignment piece 3 can be installed from above by interlocking notch 24 with notch 33. The thickness of alignment piece 3 is such that it easily slides closely between the adjacent panel modules 12, in the same manner that webbing 21 of support piece 2 had slid between adjacent panel modules 12 in a perpendicular direction to that of alignment piece 3. As a result, all four of the panel modules 12 at a corner intersection of four adjacent panels are held in place.

It should be understood that alignment piece 3 is used only for the alignment and spacing of panel modules 12. Alignment piece 3 does not support any weight. This is done solely by support piece 2. Nonetheless, alignment piece 3 helps to keep support piece 2 in the proper orientation to maximize the support capability of support piece 2. The proper positioning of alignment piece 3, and thus, support piece 2, is further aided by notches 31, 32 in alignment piece 3. Both of these notches fit over the top of the Z-rail, which constitutes upper panel rail 30. This arrangement is for maintaining the proper positioning and orientation of alignment piece 3, which in turn helps to maintain the proper orientation of support piece 2.

It should be understood that notches 31, 32 can be adjusted for the shape of the specific panel rail to which the notches are to be fit. Further, these notches can be configured to include hooking structures that could be arranged to fit under the top portion of a Z-rail.

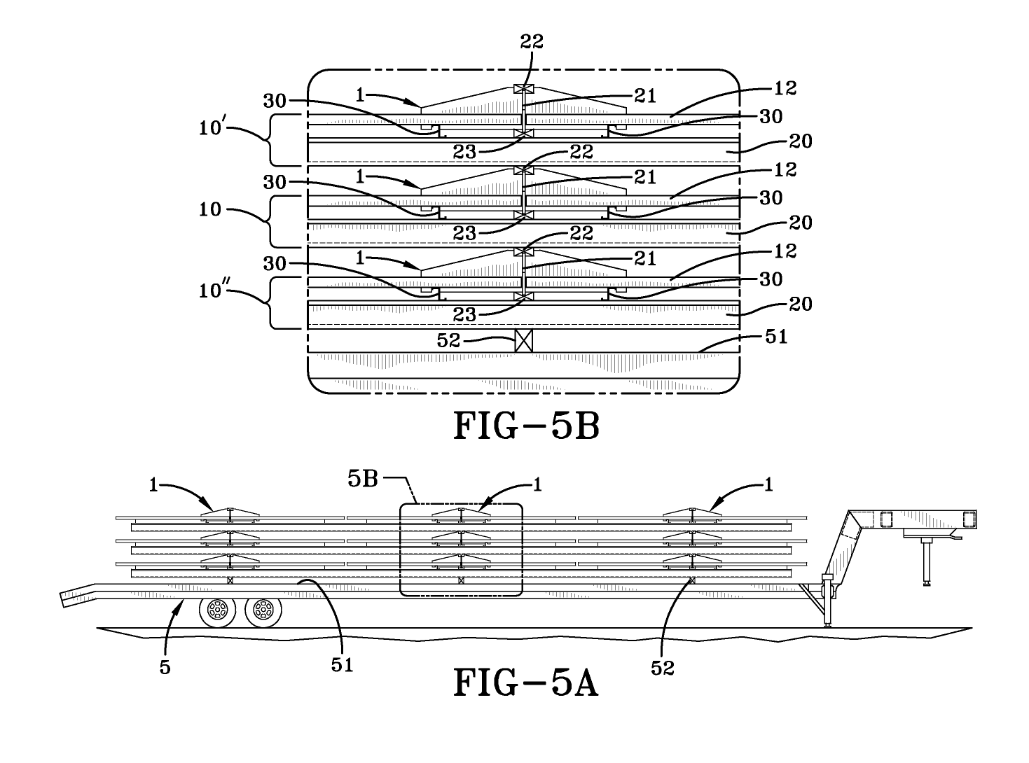

Likewise, the notches 24, 33 for interlocking the support piece 2 and alignment piece 3 need not be simple cuts as shown in FIGS. 3 and 4. Rather, other arrangements are possible. Further, while alignment piece 3 does not provide any support for the weight, which is transmitted through support piece 2, alignment piece 3 can be configured in any number of configurations that would help provide support.

In the existing solar panel arrangements depicted in the photographs of Appendix 1, crib structure 1 is made of wood. Plywood pieces (between ¼″ and ¾″) are arranged between four adjacent panel modules 12. The upper and lower bearing pieces 22 and 23 are constituted by “2×4” lengths of wood. Clearly this is a very economical arrangement because of the inexpensive materials being used. Further, because of the lack of cost for providing crib structure 1, these are easily discarded if it is not feasible to retrieve and reuse them.

Also, because wooden pieces are involved, different arrangements, besides notches 24, 33 can be used to connect the alignment piece 3 with the support piece 2. Notch 24 need not be cut into upper bearing piece 22. Rather, the upper bearing piece 22 can be added to the webbing 21 after alignment piece 3 has been interlocked with support piece 2. Connection between the alignment piece 3 and the support piece 2 can be facilitated with glue, screws, nails, or any other appropriate means to provide a stable connection between alignment piece 3 and support piece 2.

While “2×4's” and plywood are cheap, convenient materials for crib structure 1, other materials can be used. For example, molded plastic will serve as well to create the spacing capability and the weight support capability found in the wooden structures depicted in Appendix 1. Some materials, such as ABS, are far more expensive than wood, but far stronger and more durable. As such, crib structures would not be discarded after use. Rather, they could be retrieved and reused many times over.

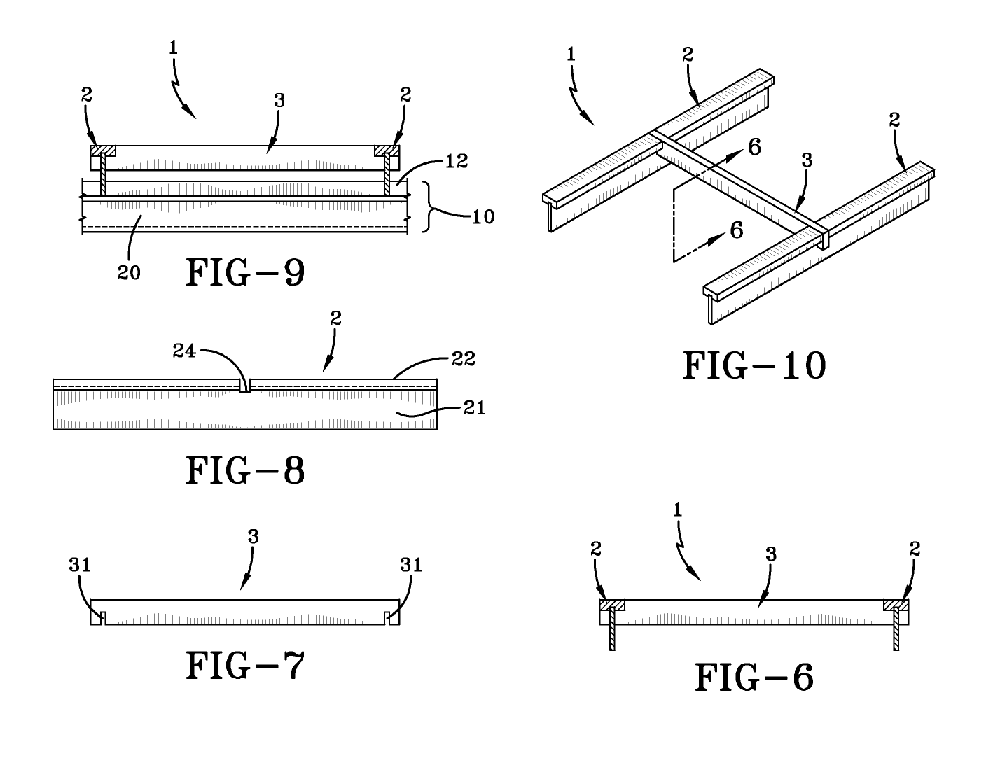

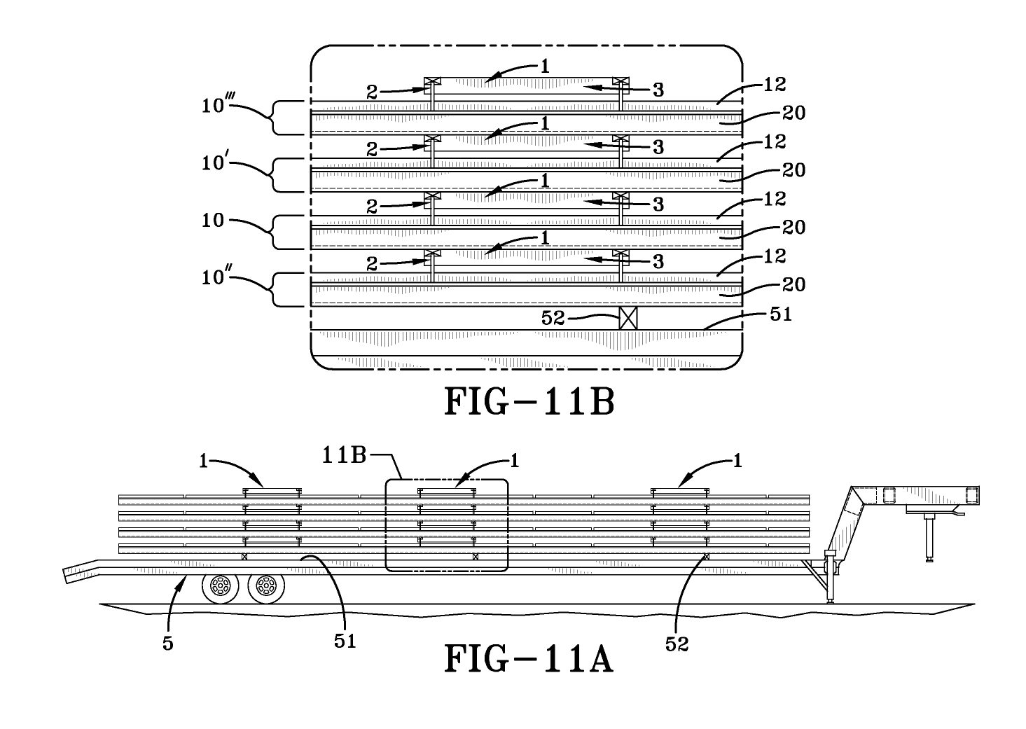

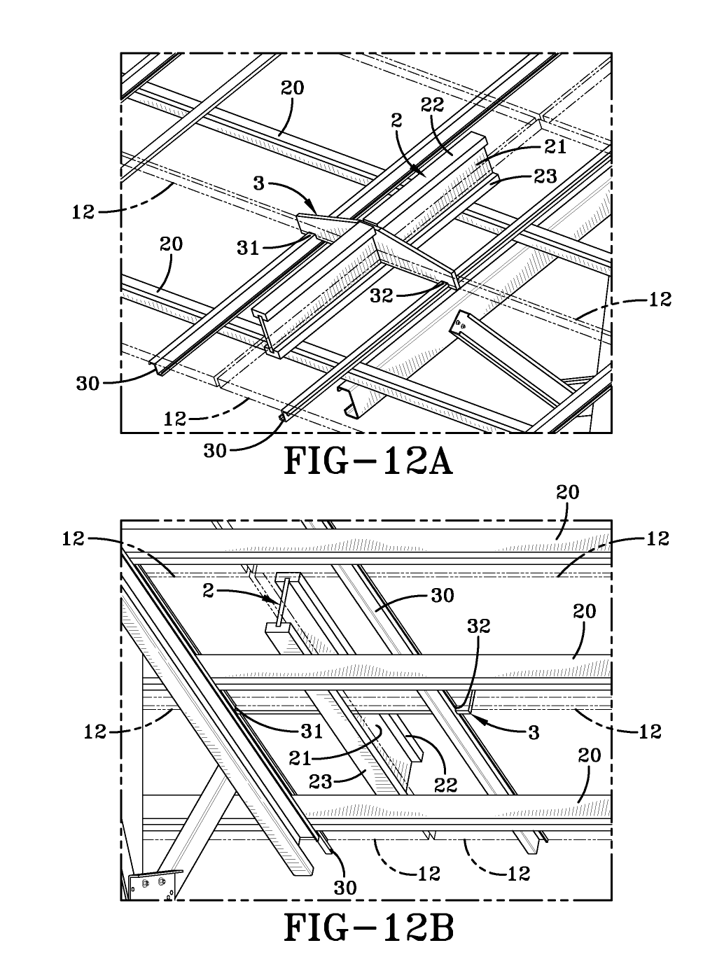

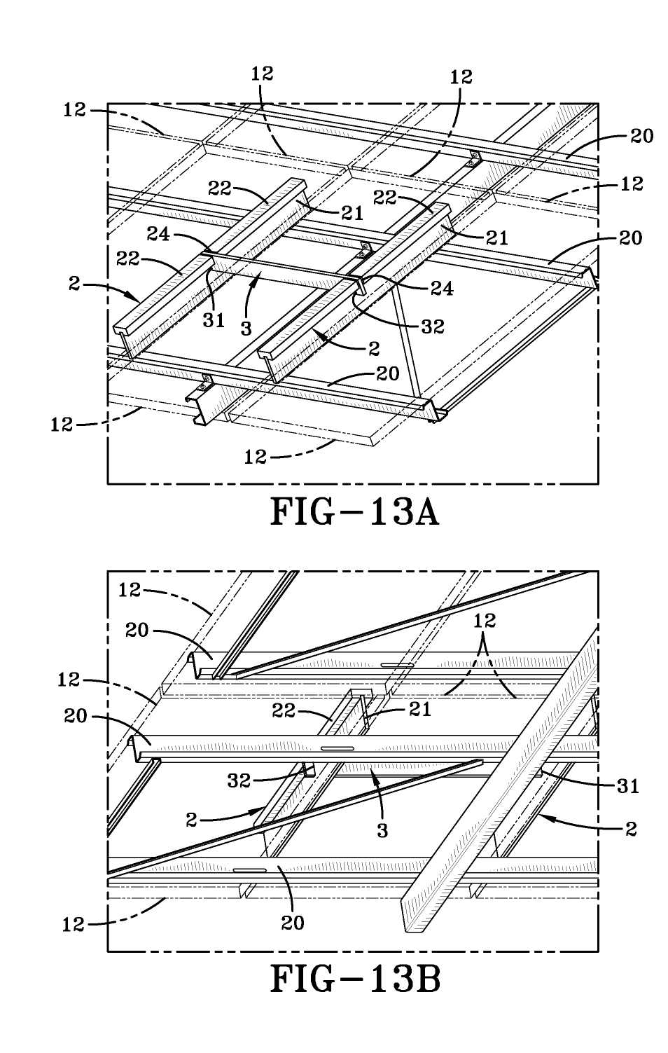

FIGS. 6-11B depict a second embodiment of the present invention. In this embodiment, crib structure 1 is modified so that some of the spacing and alignment capability is eliminated while the support capability is increased. The second embodiment is particularly applicable for panel arrangements arranged in the “portrait” alignment in which the length of the panels runs from the bottom to the top of the array, so that greater alignment is needed in this particular direction. The second embodiment is also particularly applicable when panel rail 30 is eliminated and the panel modules 12 rest directly upon lower support joist 20, as depicted in FIGS. 9, 11A and 11B.

The same drawing designation numerals are used in FIGS. 6-11B as are used in FIGS. 1-5B, to better correlate the analogous parts of the two embodiments with each other. FIG. 6 depicts a side view of crib structure 1, with a side view of alignment piece 3 and end views of two support pieces 2. It is clear that the difference in the second embodiment is that two support pieces 2 are connected together with a single alignment piece 3. However, this embodiment admits to variations so that multiple alignment pieces can be used to connect together the two support pieces 2.

Also, support pieces 2 have only an upper bearing piece 22. The end of webbing 21 rests on the single portion of the panel-populated support rack section 10, which is constituted solely by lower support joist 20. Support joist 20 is preferably a Z-purlin, on which panel modules 12 can easily be attached. Webbing 21 of support piece 2 fits in the space between adjacent panel modules 12. Sufficient weight support is provided by the use of two support pieces 2, rather than a single such support piece as is done with the first embodiment (FIGS. 1-5B).

A major distinction between the first embodiment and the second embodiment is that notches 31 and 32 on alignment piece 3 are not used to attach two panel rails. Rather, they interface with notch 24 of the corresponding support pieces 2. This is best illustrated in the top perspective view of FIG. 10. As is readily apparent, FIG. 10 depicts a configuration that is particularly appropriate for the “portrait” arrangement of solar panel modules 12. The configuration of FIG. 10 allows support pieces 2 to flank a single solar panel module 12, providing vertical support (from above and below) to protect the solar panel module 12, as well as spacing the solar panel module 12 from the solar panel modules on either side of the first solar panel module 12.

FIGS. 11A and 11B depict one advantage of the second embodiment over the first, increased vertical strength. This is due to the fact that there are twice as many support structures 2 in each crib structure 1 in the second embodiment as is found in the first embodiment. As a result, a greater level of stacking is facilitated, as depicted in FIGS. 11A and 11B. As with the first embodiment, support structures can be slid between adjacent panel modules 12 from the side of the open trailer. Because there is nothing to interfere with the joining, perpendicular alignment structure, two support structures 2 can be inserted at the same time with the alignment piece 3 already attached. The result is that the entire crib structure 1 can be easily inserted as one piece.

As with the first embodiment, the crib structure 1 of the second embodiment can be fabricated from inexpensive materials such as plywood and “2×4's”. One advantage of the second embodiment is that the structure is less complex than the first embodiment while providing greater vertical support. This means that the populated support rack sections 10 can be stacked higher, thereby utilizing the full capacity of trailer 5. In this way, overall transport is more efficient, and costs can be lowered, thereby lowering the cost of installation, and rendering the overall capital investment in the solar panel array more attractive to a potential investor.

While a number of crib structures have been described by way of example, the present invention is not limited thereto. Rather, the present invention should be considered to include any and all variations, permutations, modifications, adaptations, derivations, and embodiments that would occur to one skilled in this art having possession of the teachings of the present invention. Accordingly, the present invention should be construed as being limited only by the following claims.

What is claimed is:

1. A panel array having multiple adjacent panels with at least one space therebetween, said panel array supported by a multi-tiered, two-directional support system having a least a plurality of upper panel rails supported by multiple structural elements of a lower support tier, and a panel separation and protection system arranged between at least two of said panels, said panel separation and protection system comprising:
a) at least one support piece arranged in a first space between at least two adjacent panels; and,
b) an alignment piece, interlocking with said support piece and arranged substantially perpendicular to said support piece, said alignment piece being arranged to hold said support piece in place.

2. The panel array of claim 1, wherein said at least one support piece comprises:
a) an intermediate piece having a thickness configured to fill said first space between said adjacent panels and a height configured to extend above an upper surface of said adjacent panels, and a length extending along a length of said two adjacent panels; and,
b) at least one upper bearing piece extending along said length of said intermediate piece, and extending laterally beyond said thickness of said intermediate piece.

3. The panel array of claims 2, wherein said at least one support piece further comprises a notch in said said intermediate piece, said notch being sized to accommodate a thickness of said alignment piece for locking said alignment piece perpendicular to said support piece.

4. The panel array of claim 3, wherein said alignment piece comprises at least one notch configured to interface with said notch in said intermediate piece.

5. The panel array of claim 4, wherein said at least two adjacent panels comprise solar panels, and said upper bearing piece is configured to extend above and over said solar panels.

6. The panel array of claim 5, wherein said support piece further comprises a lower bearing piece arranged on said intermediate piece opposite said upper bearing piece, said upper and lower pieces and said intermediate piece, forming an I-beam configuration.

7. The panel array of claim 6, wherein said lower bearing piece rests on two adjacent structural elements of said lower support tier.

8. The panel array of claim 7, wherein said alignment piece extends over at least two adjacent upper panel rails.

9. The panel array of claim 8, wherein said alignment piece is arranged in a second space between two pairs of adjacent panels, thereby holding all four panels in alignment.

10. The panel array of claim 9, wherein said alignment piece comprises two notches, each said notch configured to fit over and lock with a top portion of corresponding adjacent panel rails.

11. The panel array of claim 10, wherein said panel separation and protection system is arranged between four adjacent panels at adjacent corners thereof.

12. The panel array of claim 5, wherein said panel separation and protection system comprises two support pieces, wherein said alignment piece extends between said two support pieces and interfaces with each said support piece.

13. The panel array of claim 12, wherein said alignment piece comprises two notches, each said notch configured to interface with said notch on each of said support pieces.

14. The panel array of claim 13, wherein said alignment piece is spaced from and extends across one of said at least two adjacent panels between said two support pieces.

15. The panel array of claim 14, wherein said intermediate pieces of said two support pieces extend across two adjacent upper panel rails and rests thereupon.

16. The panel array of claim 15, wherein one of said support pieces is arranged in the first gap between corresponding longitudinal edges of said two adjacent panels.

17. A method of protecting sections of panels grouped on segments of two-dimensional, multi-tier support arrays, each of said support arrays having at least upper panel rails and lower support tier elements, said method comprising the steps of:
a) attaching said panels to said upper panel rails of multiple segments;
b) placing protectors to extend above said panels in selected spaces between adjacent panels, said protectors resting on at least part of said two-dimensional, multi-tier support array of said segment;
c) attaching alignment pieces to lock with said protectors, maintaining said protectors in position; and,
d) stacking multiple segments on each other so that said lower support tier elements of an upper segment are resting on at least one of said protectors of a lower segment.
